(19) United States
(12) Patent Application Publication
(10) Pub. No.: US 2001/0040292 A1
(43) Pub. Date: Nov. 15, 2001

(54) Semiconductor device having a contact plug formed by a dual epitaxial layer and method for fabricating the same

(76) Inventors: Seung-Ho Hahn, Kyoungki-do (KR); Dae-Hee Weon, Kyoungki-do (KR); Jeong-Youb Lee, Kyoungki-do (KR); Jung-Ho Lee, Kyoungki-do (KR); Chung-Tae Kim, Kyoungki-do (KR)

Correspondence Address: MARSHALL, O'TOOLE, GERSTEIN, MURRAY & BORUN, 6300 SEARS TOWER, 233 SOUTH WACKER DRIVE, CHICAGO, IL, 60606-6402, US

(21) Appl. No.: 09/770,331

(22) Filed: Jan. 26, 2001

(30) Foreign Application Priority Data
Jan. 28, 2000 (KR) 2000-4332

(51) Int. Cl. H01L 23/52

(52) U.S. Cl. 257/750; 438/300; 438/607

(57) ABSTRACT

During selective epitaxial growth processing using LPCVD equipment, a SiGe epitaxial layer and a Si epitaxial layer are sequentially formed so that lateral overgrowth that could occur in formation of only Si epitaxial layer can be effectively restricted. By adjusting Ge density, SiGe migration is induced at selective epitaxial growth temperatures for forming the conventional Si epitaxial layer. And, by utilizing the internal stress of SiGe and lattice mismatch between the SiGe epitaxial layer and the Si epitaxial layer, the lateral overgrowth is restricted. Furthermore, by hydrogen thermal processing, surface topology of the epitaxial layer is improved.

### FIELD OF THE INVENTION

The present invention relates to a semiconductor device fabricating method, and, more particularly, to a semiconductor device having contact plug formed by dual epitaxial layer and a method for fabricating the same.

### BACKGROUND OF THE INVENTION

In a conventional self align contact method, processing can be simplified because it does not employ a contact plug. However, due to increased integration, the self align contact processing margins can become insufficient so that the substrate can be damaged during etching processing.

To solve this problem, a method for forming epitaxial layer for a plug by selective epitaxial growth processing before the etching processing has been studied. On the other hand, attempts at developing a contact plug formation method using selective epitaxial growth processing and common contact formation processing have been made in addition to the self align contact formation processing.

The conventional contact plug formation processing forms an epitaxial layer of about 1000 Å thickness by using the selective epitaxial growth before or after the self align contact etching processing. In either case, the epitaxial layer is doped to reduce contact resistance and, as the doping method, ion injection or in-situ doping in which doping gas is released during the selective epitaxial layer growth is used.

The contact plug formation processing using the selective epitaxial growth as described above has numerous problems.

First, the method in which the selective epitaxial layer is formed before the self align contact etching processing takes place and is limited in terms of the thickness of the epitaxial layer due to lateral overgrowth. That is, as shown in FIG. 1, when a Si epitaxial layer 16 is formed by using the selective epitaxial growth on an exposed silicon substrate 10 after forming a word line and an insulation film spacer 15 formed by polysilicon film 13 and metal film 14 on a gate oxide film 12, lateral overgrowth occurs in parallel after growing Si epitaxial layer 16 to a predetermined thickness. Accordingly, the field oxide 11 is covered with the epitaxial layer 16. For example, in the selective epitaxial layer growth processing using a conventional LPCV (low pressure chemical vapor deposition) method, the Si epitaxial layer 16 should not be grown to a height (about 3000 Å thickness) of a typical word line or gate electrode, because of the lateral overgrowth problem. Instead, the thickness of the Si epitaxial layer 16 should be restricted to 1000 Å to retard the lateral overgrowth.

In order to avoid this restriction of the Si epitaxial layer thickness, a selective epitaxial growing method using an UHVCVD (ultra high vacuum chemical vapor deposition) equipment has been studied. However, the UHVCVD equipment is less favorable in cost and installation space than the LPCVD equipment. Furthermore, UHVCVD equipment is difficult to operate and additional costs are incurred keeping the requisite ultra high vacuum state. Therefore, even if such a process is developed successfully, it most likely will not be employed by manufacturers.

On the other hand, the method in which the selective epitaxial layer is grown after the self align contact etching processing is complete still has the problem of the self align contact etching processing as described above. Even under the successful processing, it results in cost increase due to low yield selective epitaxial layer growth processing instead of a simple processing of polycrystal silicon deposition.

### SUMMARY OF THE DISCLOSED DEVICES AND METHODS

A semiconductor device having a contact plug capable of restricting lateral overgrowth of the epitaxial layer during formation of the epitaxial layer is provided by using a selective epitaxial growth on an exposed silicon layer.

The disclosed semiconductor device includes: a silicon substrate; a word line formed on the silicon substrate, its top and side being covered with an insulation film; and a contact plug having a SiGe epitaxial layer and a Si epitaxial layer layered between the word line and the silicon substrate.

The disclosed method for fabricating a semiconductor device includes the following steps: forming the SiGe epitaxial layer on the exposed silicon substrate by selective epitaxial growth; and forming the Si epitaxial layer on the SiGe epitaxial layer by selective epitaxial growth.

In a further refinement of the disclosed method, the method includes the steps of: (a) forming a word line on a silicon substrate on which field oxide formation is completed; (b) forming an insulation film pattern and insulation spacers on top and side of the word line, respectively; (c) forming a SiGe epitaxial layer on the exposed silicon substrate between the insulation spacers by selective epitaxial growth; and (d) forming a Si epitaxial layer on the SiGe epitaxial layer by selective epitaxial growth to form contact plug having the SiGe epitaxial layer and the Si epitaxial layer.

### BRIEF DESCRIPTION OF THE DRAWINGS

The above features of the disclosed devices and methods will become apparent from the following description taken in conjunction with the accompanying drawings, wherein:

FIG. 1 is a sectional view illustrating a problem in contact plug formation using conventional selective epitaxial growth;

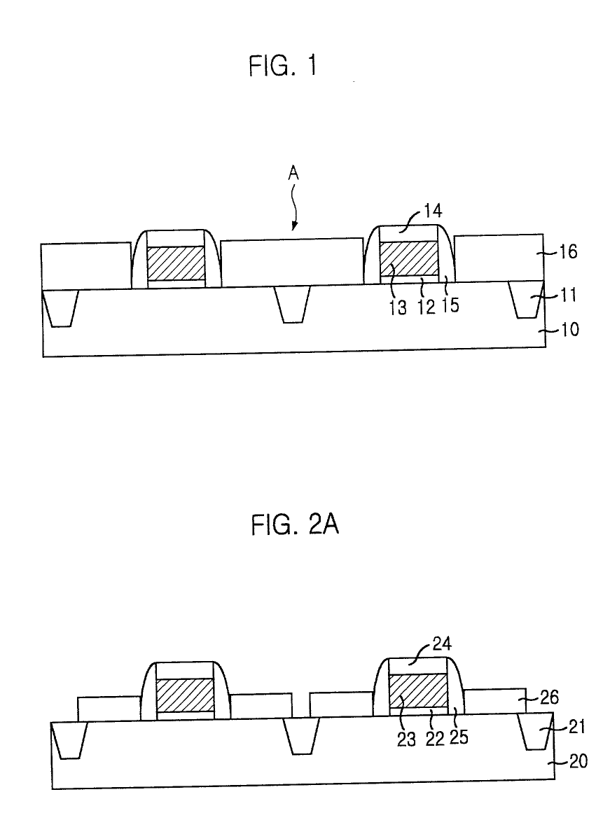

FIGS. 2A to 2C are sectional views illustrating contact plug formation using selective epitaxial growth in accordance with the disclosed methods; and

FIGS. 3A and 3B are SEM photos of the conventional contact plug and the disclosed contact plug, respectively.

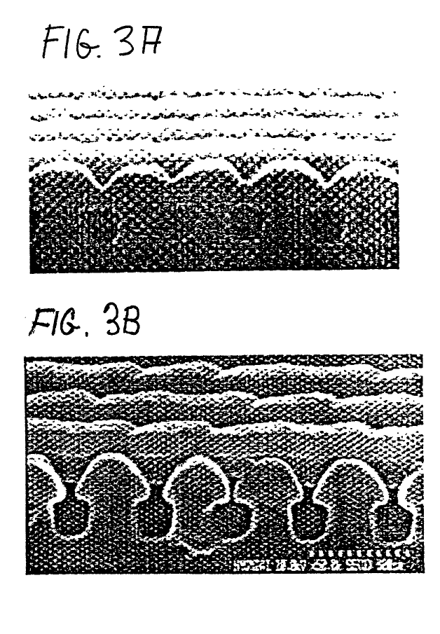

### DETAILED DESCRIPTION OF THE PRESENTLY PREFERRED EMBODIMENTS

In the disclosed method, during selective epitaxial growth processing using a LPCVD equipment, SiGe epitaxial layer and Si epitaxial layer are sequentially formed so that lateral overgrowth that could occur in formation only Si epitaxial layer can be effectively restricted.

In the disclosed method, by adjusting the Ge density, SiGe migration is induced at selective epitaxial growth temperatures for forming the conventional Si epitaxial layer. And by utilizing internal stress of the SiGe and lattice mismatch between the SiGe epitaxial layer and the Si epitaxial layer, the lateral overgrowth is restricted. Furthermore, by utilizing hydrogen thermal processing, surface topology of the epitaxial layer is improved.

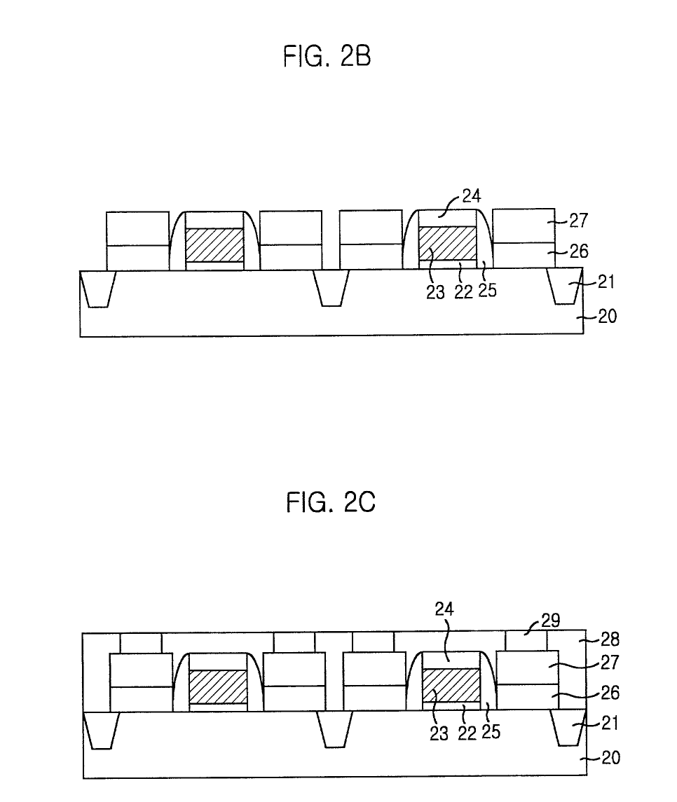

A method for forming contact plug using selective epitaxoal layer growth will be described in conjunction with accompanying drawings FIGS. 2A to 2C.

First, as shown in FIG. 2A, gate oxide 22 having the thickness ranging from about 30 Å to about 100 Å is formed on a silicon substrate 20 in which an isolation film, e.g., a field oxide 21, is formed through LOCOS (Local Oxidation of Silicon) or STI (Shallow Trench Isolation) processing. A word line 23 is formed with a polysilicon film and tungsten or tungsten silicide. A nitride film hard mask 24 and an insulation film spacer 25 are formed on top and to the side of the word line, respectively.

The insulation film spacer 25 at the side of the word line 23 is formed by forming a nitride film having a thickness ranging from about 100 Å to about 500 Å on the silicon substrate 20 on which the word line 23 is formed. Then an etching process is carried out.

To eliminate residual carbonate hydrogen film and oxide film on the exposed silicon substrate 20, a piranha cleaning using mixture solution of H₂O₄ and H₂O₂ and SC-1 cleaning using mixture solution of NH₄OH, H₂O₂ and H₂O is carried out and then the device is soaked in an HF solution outside of the chamber. During these cleaning processes, the residual oxide film, or native oxide film, is eliminated. Because the organic carbonated hydrogen film cannot be completely eliminated by the HF solution soaking, the piranha cleaning and the SC-1 cleaning are preferably included in the method. On the other hand, the HF solution processing can be limited to a time ranging from about 30 to about 80 seconds to minimize the loss of field oxide 21.

Next, after completion of cleaning steps, the silicon substrate 20 is inserted to a reactor (not shown). Even if the cleaned silicon substrate 20 is inserted to the reactor without any time delay, the surface of the silicon substrate 20 on which the selective epitaxial layer is to be grown is inevitably exposed in air so that a native oxide film of non-uniform thickness is formed. And, even after insertion into the reactor, the native oxide film could be formed during subsequent handing, e.g., alignment. Therefore, after insertion into the reactor, the native oxide film is eliminated by hydrogen bake processing. Hydrogen bake processing is carried out with H₂ of about 50 slm, for about 60 seconds, under a temperature of 825° C. to about 900° C. and maximum pressure of about 30 torr.

Then, by the selective epitaxial growth processing using the LPCVD equipment, a SiGe epitaxial layer 26 is formed on the exposed silicon substrate 20 as shown in FIG. 2A. In order to induce SiGe migration at a temperature that is lower than the silicon epitaxial formation temperature, the composition and temperature conditions should be controlled. The higher concentration of Ge in the SiGe epitaxial layer, the lower the migration temperature becomes. Therefore, based on the desired migration amount, the electrical characteristic of the device to be produced and energy costs, the Ge concentration and processing temperature are determined. In one embodiment of the present invention, by applying SiH₂Cl₂ at a flow rate ranging from about 50 sccm to about 300 sccm and HCL gas at a flow rate ranging from about 100 sccm to about 200 sccm at the temperature ranging from about 850° C. to about 900° C., the Si epitaxial layer 27 is formed to have a thickness approximately equal to the word line height.

When an aspect ratio defined by the thickness/lateral overgrowth of the Si epitaxial layer 27 is small, the Si epitaxial layer 27 is grown once. And when the aspect ratio is large, the Si epitaxial formation and hydrogen bake are carried out for less than 30 seconds and are repeated. Although the effect of the hydrogen bake is proportional to processing time, a processing time of less than 30 seconds has been found to be sufficient. On the other hand, the surface of the SiGe epitaxial layer 26 is processed by hydrogen bake processing at a temperature ranging from about 800° C. to about 900° C. before formation of the Si epitaxial layer 27 so as to strengthen the migration effect of the SiGe.

Then, the Si epitaxial layer 27 and the SiGe epitaxial layer 26 are doped. At this time, in order to reduce the resistance of a part to which metal is contacted during posterior metal contact processing, i.e., to form ohmic contact, additional doping is carried out on top of the epitaxial layer by ion injection.

For example, when the conductivity of a source and a drain (not shown) formed in the silicon substrate 20 at both ends of the word line is p-type, B or BF₂ is injected into Si epitaxial layer 27 and SiGe epitaxial layer 26. That is, B or BF₂ is ion-injected with a dosage ranging from about 2×10¹⁵/cm² to about 1×10¹⁶/cm², B ion-injected at 20 KeV to 50 KeV and BF² is ion-injected at 100 KeV to 250 KeV. And also, for the ohmic contact, B, BF₂, or their mixture is ion-injected with a dosage ranging from about 1×10¹⁵ to about 5×10¹⁵/cm², B injected at 1 KeV to 5 KeV and BF2 injected at 5 KeV to 20 KeV.

On the other hand, when the source and the drain are doped to n-type, As or P is ion-injected into the Si epitaxial layer 27 and the SiGe epitaxial layer 26. At this time, As or P is ion-injected with dose ranging from about 2×10¹⁵/cm² to about 1×10¹⁶/cm² and P is ion-injected at 50 KeV ro 120 KeV and As is ion-injected at 80 KeV to 200 KeV. And, for the ohmic contact, As, P or their mixture is ion-injected with dose ranging from about 1×10¹⁵/cm² to about 5×10¹⁵, P injected at 1 KeV to 10 KeV and As injected at 2 KeV to 20 KeV.

And also, an in-situ method is used for the Si epitaxial layer 27 and the SiGe epitaxial layer 26 doping in addition to the ion-injection method as described above. That is, during Si epitaxial layer 27 and SiGe epitaxial layer 26, the growth of the Si epitaxial layer 27 and SiGe epitaxial layer 26 are doped by applying P or As gas at flow rates ranging from tens of sccm to hundreds of sccm depending on doping concentration.

In FIG. 2C, after an inter-layer insulation film 28 of thickness ranging from about 5000 Å to about 15000 Å is formed on the entire structure on which the contact plug is formed by the SiGe epitaxial layer 26 and the Si epitaxial layer 27 as described above and planarized by CMP (chemical mechanical polishing, a contact hole is formed for exposing the Si epitaxial layer 27 by selective etching and then a contact 29 is formed. The inter-layer insulation film 28 is constructed by an oxide film or an APL (Advanced Planarization Layer) is formed by a BPSG (Borophosphosilicate Glass) and high density plasma chemical vapor deposition.

As described above, the disclosed method can form the epitaxial layer without overgrowth during the selective epitaxial growth processing by using the typical LPCVD without the need for expensive UHVCVD equipment so that thickness restriction of the epitaxial layer can be economically solved. Therefore, the epitaxial layer can be grown to gate height and the self align contact plug formation can be replaced with a typical contact plug formation.

Furthermore, because the contact plug has dual layers of the SiGe epitaxial layer and the Si epitaxial layer, topology of the epitaxial layer and electric characteristics thereof can be improved. That is, by forming most of the plug with the SiGe epitaxial layer of higher conductivity, contact resistance can be reduced as a whole. And, because the Si epitaxial layer is on top of the SiGe epitaxial layer, Ge exposure during cleaning or etching processing after the selective epitaxial growth processing can be prevented and posterior contact processing can be carried out in the same manner as with a single Si epitaxial layer.

While the present invention has been shown and described with respect to the particular embodiments, it will be apparent to those skilled in the art that many changes and modifications may be made without departing from the spirit and scope of the invention as defined in the appended claims.

What is claimed is:

1. A semiconductor device comprising:
a silicon substrate;
a word line formed on the silicon substrate, the word line having a top and a side that are covered with an insulation film; and
a contact plug having a SiGe epitaxial layer and a Si epitaxial layer disposed between the word line and the silicon substrate.

2. A method for fabricating a semiconductor device, the method comprising the steps of:
forming a SiGe epitaxial layer on an exposed silicon substrate by selective epitaxial growth; and
forming a Si epitaxial layer on the SiGe epitaxial layer by selective epitaxial growth.

3. A method for fabricating a semiconductor device, the method comprising the steps of:
(a) forming a word line on a silicon substrate having field oxide, the word line having a top and a side;
(b) forming an insulation film pattern on the top of the word line and forming an insulation spacers on the side of the word line;
(c) forming a SiGe epitaxial layer on an exposed portion of silicon substrate disposed between the insulation spacers by selective epitaxial growth; and
(d) forming a Si epitaxial layer on the SiGe epitaxial layer by selective epitaxial growth to form a contact plug comprising the SiGe epitaxial layer and the Si epitaxial layer.

4. The method as recited in claim 3, further comprising, after step (b) and before step (c) the step of:
(e) performing a cleaning processing to eliminate carbonated hydrogen film and oxide film on the silicon substrate.

5. The method as recited in claim 4, further comprising, after step (e) the steps of:
inserting the silicon substrate into a reactor; and
performing a bake process in a hydrogen furnace to eliminate a native oxide film.

6. The method as recited in claim 4, further comprising, after step (e) the step of:
(f) performing hydrogen bake processing.

7. The method as recited in claim 5, wherein, in step (c), the SiGe epitaxial layer is in-situ doped and, in step (d), the Si epitaxial layer is in-situ doped.

8. The method as recited in claim 5, further comprising, after step(d) the step of:
(g) doping the Si epitaxial layer and the SiGe epitaxial layer by ion-injection.

9. The method as recited in claim 5, further comprising the steps of:
(h) forming an inter-layer insulation film on the entire structure;
(i) exposing the contact plug by selectively etching the inter-layer insulation layer; and
(j) forming a contact touching the contact plug.

10. The method as recited in claim 2, wherein the SiGe epitaxial layer is fabricated using SiH₂Cl₂, HCL gas and GeH4 and the Si epitaxial layer is fabricated using SiH₂Cl₂ and HCL gas.

11. The method as recited in claim 10, wherein the SiGe epitaxial layer and the Si epitaxial layer fabricated using LPCVD.
